(19) United States
(12) Patent Application Publication
(10) Pub. No.: US 2018/0212182 A1
(43) Pub. Date: Jul. 26, 2018

(54) Light Emitting Unit and Manufacturing Method Thereof, Display Panel and Electronic Device

(71) Applicants: BOE Technology Group Co., Ltd., Beijing (CN); Hefei Xinsheng Optoelectronics Technology Co., Ltd, Anhui (CN)

(72) Inventors: Yongchao Huang, Beijing (CN); Yuankui Ding, Beijing (CN); Leilei Cheng, Beijing (CN); Min He, Beijing (CN)

(73) Assignees: BOE Technology Group Co., Ltd., Beijing (CN); Hefei Xinsheng Optoelectronics Technology Co., Ltd ., Anhui (CN)

(21) Appl. No.: 15/567,816

(22) PCT Filed: May 19, 2017
(86) PCT No.: PCT/CN2017/085076

§ 371 Date: Oct. 19, 2017

(30) Foreign Application Priority Data
May 30, 2016 (CN) 201610371608.4

(51) Int. Cl. H01L 51/52; H01L 51/50

(52) U.S. Cl. CPC H01L 51/5203; H01L 51/5092; H01L 51/5072; H01L 51/5056

(57) ABSTRACT

A light emitting unit and a manufacturing method thereof, a display panel and an electronic device. The light emitting unit includes a first electrode, a second electrode and a light emitting layer between the first electrode and the second electrode. A material of the light emitting layer 3 includes graphene. The light emitting layer of the light emitting unit can emit light at a single wavelength.

### TECHNICAL FIELD

Embodiments of the present disclosure relate to a light emitting unit and a manufacturing method thereof, a display panel and an electronic device.

### BACKGROUND

Organic light emitting display devices have been widely used because of low power consumption and high resolution thereof. An organic light emitting display device comprises a plurality of light emitting units, and each of the light emitting unit comprises a first electrode, a second electrode and a light emitting layer between the first electrode and the second electrode. Under the action of an external electric field, the first electrode and the second electrode inject electrons and holes to the light emitting layer, respectively. The electrons and holes recombine in the light emitting layer and allow the light emitting layer to emit light. The light emitting layers made of different materials emit light with different colors, some light emitting layers can emit red light, some light emitting layers can emit green light and some light emitting layers can emit blue light, thus enabling the display device to display colorful pictures.

### SUMMARY

An embodiment of the present disclosure provides a light emitting unit, the light emitting unit comprises: a first electrode, a second electrode and a light emitting layer between the first electrode and the second electrode, and a material of the light emitting layer comprises graphene.

Optionally, for example, the graphene is graphene oxide.

Optionally, the light emitting unit further comprises an electron transport layer and a hole transport layer; the electron transport layer is arranged between the light emitting layer and the first electrode and the hole transport layer is arranged between the light emitting layer and the second electrode.

Optionally, the light emitting unit further comprises an electron injection layer and a hole injection layer; the electron injection layer is arranged between the electron transport layer and the first electrode, the hole injection layer is arranged between the hole transport layer and the second electrode, and a material of the electron injection layer and a material of the hole injection layer comprise graphene.

Optionally, oxidation degrees of the graphene of the electron injection layer, the graphene of the hole injection layer and the graphene of the light emitting layer are different from each other.

Optionally, a ratio of a number of oxygen atoms to a number of carbon atoms in the graphene of the hole injection layer is greater than or equal to 0 and less than or equal to 0.48, and a ratio of a number of oxygen atoms to a number of carbon atoms in the graphene of the electrons injected layer is greater than or equal to 0.57 and less than or equal to 1.

Optionally, a ratio of a number of oxygen atoms to a number of carbon atoms in the graphene of the light emitting layer is greater than or equal to 0.5 and less than or equal to 0.77.

Optionally, where a voltage applied across the first electrode and the second electrode is 0˜15V, the light emitting layer emits red light at a single wavelength; where a voltage applied across the first electrode and the second electrode is 15˜30V, the light emitting layer emits green light at a single wavelength; and where a voltage applied across the first electrode and the second electrode is 35˜50V, the light emitting layer emits blue light at a single wavelength.

Another embodiment of the present disclosure provides a display panel, comprising the light emitting unit.

Still another embodiment of the present disclosure provides an electronic device, comprising the light emitting unit.

Further still another embodiment of the present disclosure provides a method for manufacturing a light emitting unit, comprising: providing a first electrode and a second electrode; forming a light emitting layer between the first electrode and the second electrode, and a material of the light emitting layer comprises graphene.

### BRIEF DESCRIPTION OF THE DRAWINGS

The present disclosure will become more fully understood from the detailed description given hereinafter and the accompanying drawings which are given by way of illustration only, and thus are not limitative of the present disclosure and wherein:

FIG. 1 is a structural schematic diagram of the light emitting unit in a first embodiment of the present disclosure;

FIG. 2 is a flow diagram of the method of manufacturing a light emitting unit in a fourth embodiment of the present disclosure;

FIG. 3 is a flow diagram of the method of manufacturing a light emitting unit in a fifth embodiment of the present disclosure; and

FIG. 4 is a structural schematic diagram of the electronic device in an embodiment of the present disclosure.

### REFERENCE CHARACTERS

1—first electrode; 2—second electrode; 3—light emitting unit; 4—electron transport layer; 5—hole transport layer; 6—electron injection layer; 7—hole injection layer.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

The inventors of the present disclosure note in the research that in the light emitting unit of an organic light emitting display device, the wavelength of the light with a certain color emitted by the light emitting layer is in a range of value, rendering the color gamut of the light with the color to be narrow and in turn making the color of the picture displayed by the display device dim.

In order to make objects, technical details and advantages of the embodiments of the disclosure apparent, the embodiments of the disclosure will be described further in detail in connection with the drawings.

### Embodiment 1

In the light emitting unit of the organic light emitting display device of this embodiment, the wavelength of the light with a certain color emitted by the light emitting layer is in a range of value. For example, an AMOLED (active-matrix organic light emitting diode) display device comprises a plurality of light emitting units, some of which can emit red light, and the wavelengths of the red light emitted by these units are in a range of value, from 600 nm to 700 nm; similarly, the wavelengths of the green light and the blue light emitted by other light emitting units are also in a range of value. This case renders the color gamut of red light, green light and blue light to be narrow, thus the color of red light, green light and blue light is dim, and the color of the mixed light of red light, green light and blue light is dim in turn, which makes the color of the picture displayed by the display device dim.

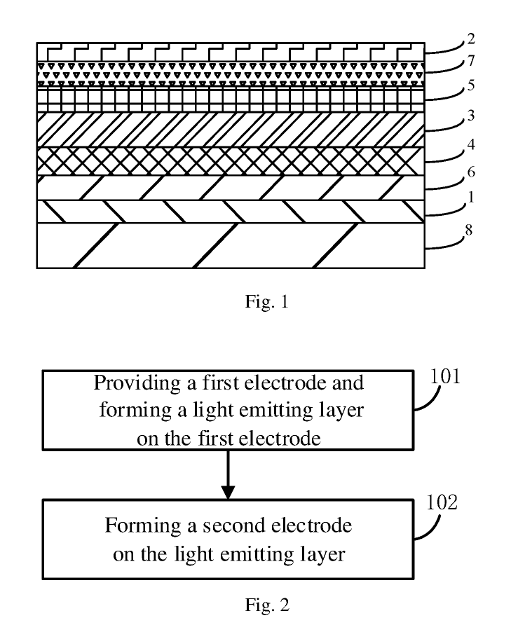

As for the problem that the wavelengths of the light with a certain color emitted by a light emitting layer of a light emitting unit of an organic light emitting display device are in a range of value, making the color gamut of the light with the color narrow and making the color of the picture displayed by the display device dim, the embodiment of the present disclosure provides a light emitting unit that can be used for an organic light emitting display device, as shown in FIG. 1, the light emitting unit comprises a first electrode 1, a second electrode 2 and a light emitting layer 3 between the first electrode 1 and the second electrode 2. In the embodiment of the present disclosure, the first electrode 1 can be a cathode, the second electrode 2 can be an anode, and electrons are transported to the light emitting layer 3 by the cathode, and holes are transported to the light emitting layer 3 by the anode. A material of the light emitting layer 3 comprises graphene material.

For example, the graphene of the light emitting layer 3 is oxidized to a certain degree, namely graphene oxide. When the graphene is oxidized, the oxidation degree of the graphene can be controlled. Where different driving voltages are applied to both sides of the light emitting layer that is made of graphene, holes and electrons injected by the cathode and the anode respectively recombine in the graphene, allowing light to be emitted; the light emitting layer made of graphene can emit light with different colors, and the emitted light is at a certain single wavelength. Therefore, a graphene can be elected as the material of the light emitting layer 3, such as the graphene that is oxidized to a certain degree; by applying different voltages to the graphene that is oxidized to a certain degree, the graphene that is oxidized to a certain degree can emit red light, green light or blue light at a single wavelength.

In the embodiment of the present disclosure, by using graphene to prepare a light emitting layer 3 and using the first electrode 1 and the second electrode 2 to inject holes and electrons to the light emitting layer 3, when applying different driving voltages to the light emitting layer 3, the light emitting layer 3 can emit light at a single wavelength. Compared with the light with the wavelength in a certain range of value emitted by the light emitting layer 3 made of an organic light emitting material, the embodiment enlarges the color gamut of the emitted light, make the colors of the display device more vivid and improves users' experience.

In the embodiment of the present disclosure, by controlling the oxidation degrees of graphene, a ratio of an amount of oxygen atoms to an amount of carbon atoms in the graphene of the light emitting layer 3 is greater than or equal to 0.5 and less than or equal to 0.77, such as 0.55, 0.6, 0.65, 0.7, 0.75 or 0.77.

In the embodiment, for example, the graphene can be commercially available products. The preparation methods for graphene comprise micromechanical exfoliation method, epitaxial growth method, graphite oxide reduction method, vapor phase deposition method, and so on. At present, the preparation process of graphene oxide is relatively mature, such as chemical methods, comprising Brodie method, Staudenmaier method, Hummers method, and so on. The preparation principle of these methods involves forming the graphite intercalation compounds of stage 1 under the action of strong acid along with a small amount of strong oxidant on the graphite, then the graphite intercalation compounds continue to undergo deeply liquid phase oxidation under the action of excessive strong oxidant, and are hydrolyzed to produce graphite oxide, finally, the mixture of graphite oxide and water is subjected to ultrasounding or long time stirring to obtain graphene oxide. The oxidation degree and the synthesis process of the product are related to the reaction time, and can be measured by the ratio of the number of C atom to the number of O atom.

As shown in FIG. 1, in one exemplary embodiment of the present disclosure, the light emitting unit can further comprise an electron transport layer 4 and a hole transport layer 5; the electron transport layer 4 is arranged between the light emitting layer 3 and the first electrode 1, and the hole transport layer 5 is arranged between the light emitting layer 3 and the second electrode 2.

In the embodiment of the present disclosure, the injection rate and the injection volume of electrons and holes injected to the light emitting layer 3 can be adjusted by the electron transport layer 4 and the hole transport layer 5. The electron transport layer 4 and the hole transport layer 5 can be made of known materials, for example, the materials of the hole transport layer comprise amine derivatives, and the materials of the hole transport layer comprise metal compounds or organic metal salts.

As shown in FIG. 1, in another exemplary embodiment of the present disclosure, the light emitting unit can further comprise an electron injection layer 6 and a hole injection layer 7; the electron injection layer 6 is arranged between the electron transport layer 4 and the first electrode 1, and the hole injection layer 7 is arranged between the hole transport layer 5 and the second electrode 2. For example, the materials of the hole injection layer 7 and the electron injection layer 6 comprise graphene. In addition, the materials of the hole injection layer 7 and electron injection layer 6 can also be other known materials, for example, the materials of the hole injection layer comprise fluorinated hydrocarbons, porphyrin derivatives, or P-Doped amine derivatives; the materials of the electron injection layer comprise alkali metal halides, alkaline earth metal halides, alkali metal oxides or metal carbonate compounds.

In the embodiment of the disclosure, using graphene as the materials of the electron injection layer 6 and the hole injection layer 7 can increase the injection rate of the electrons and holes into the light emitting layer 3, reduce the energy loss of electrons and holes in the transporting process, and improve the luminance of the display device.

For example, the oxidation degrees of graphene of the hole injection layer 7, the electron injection layer 6 and the light emitting layer 3 can be different from one another.

In the embodiment of the disclosure, a ratio of the number of oxygen atoms to the number of carbon atoms in the graphene of the hole injection layer 7 is greater than or equal to 0 and less than or equal to 0.48, such as 0, 0.05, 0.1, 0.15, 0.20, 0.25, 0.3, 0.35, 0.4, 0.45 and 0.48; a ratio of the number of oxygen atoms to the number of carbon atoms in the graphene of the electrons injection layer is greater than or equal to 0.57 and less than or equal to 1, such as 0.57, 0.6, 0.65, 0.7, 0.75, 0.8, 0.85, 0.9 and 1.

In the embodiment of the disclosure, where the ratio of the number of oxygen atoms to the number of carbon atoms in the graphene of the light emitting layer 3 is greater than or equal to 0.5 and less than or equal to 0.77, and the voltage applied across the first electrode 1 and the second electrode 2 is 0˜15V, the light emitting layer 3 can emit red light at a single wavelength; where the voltage applied across the first electrode 1 and the second electrode 2 is 15˜30V, the light emitting layer 3 can emit green light at a single wavelength; and where the voltage applied across the first electrode 1 and the second electrode 2 is 35˜50V, the light emitting layer 3 can emit blue light at a single wavelength.

In the embodiment of the disclosure, the light emitting layer 3 made of graphene can emit light of different colors at a single wavelength by controlling the voltages applied to the light emitting layer 3 of the light emitting unit respectively. A plurality of light emitting units emit light of different colors by applying different voltages to the light emitting units, thus the display device achieves colorful display.

In the light emitting unit of the embodiment of the disclosure, using graphene as the material of the light emitting layer 3 of the light emitting unit, using the first electrode 1 and the second electrode 2 to inject holes and electrons into the light emitting layer 3, upon applying different voltages to the light emitting layer 3, the light emitting layer 3 can emit light at a single wavelength. Compared with the light with wavelengths in a range of value emitted by a light emitting layer 3 made of an organic material, the embodiment of the disclosure enlarges the color gamut of light, makes the colors of the display device more vivid, and improves users' experience. In addition, the graphene can be further used for the hole injection layer 7 and the electron injection layer 6 of the light emitting unit, and the oxidation degrees of the graphene of the hole injection layer 7, the electron injection layer 6 and the light emitting layer 3 are different from each other. The hole injection layer 7 and the electron injection layer 6 made of the graphene can improve the injection rate of holes and electrons into the light emitting layer 3, reduce the energy loss of electrons and holes in the transporting process and improve the luminance of the display device.

In the embodiment of the disclosure, for example, the thickness of the electron transport layer ranges from about 100 Å to 500 Å and the thickness of the hole transport layer ranges from about 50 Å to 5000 Å. The thickness of the light emitting layer ranges from about 50 Å to 1000 Å. The thickness of the electron injection layer ranges from about 10 Å to 300 Å and the thickness of the hole injection layer ranges from about 100 Å to 500 Å.

### Embodiment 2

The embodiment of the present disclosure provides a display panel, such as an OLED (Organic Light-Emitting Diode) display panel or an AMOLED display panel. The display panel comprises the light emitting unit described in embodiment 1.

In the display panel of this embodiment of the disclosure, using graphene as the material of the light emitting layer 3 of the light emitting unit, using the first electrode 1 and the second electrode 2 to inject holes and electrons into the light emitting layer 3, upon applying different voltages to the light emitting layer 3, the light emitting layer 3 can emit light at a single wavelength. Compared with the light with wavelengths in a range of value emitted by a light emitting layer 3 made of an organic material, the embodiment of the disclosure enlarges the color gamut of light, makes the colors of the display device more vivid, and improves users' experience. In addition, the graphene can be further used for the hole injection layer 7 and the electron injection layer 6 of the light emitting unit, and the oxidation degrees of the graphene of the hole injection layer 7, the electron injection layer 6 and the light emitting layer 3 are different from each other. The hole injection layer 7 and the electron injection layer 6 made of the graphene can improve the injection rate of holes and electrons into the light emitting layer 3, reduce the energy loss of electrons and holes in the transporting process and improve the luminance of the display device.

### Embodiment 3

This embodiment of the disclosure provides an electronic device, such as a display device, an illumination device and so on. The display device provided by the embodiment of the disclosure can be any product or component with a display function, such as a mobile phone, a tablet computer, a television, a display, a notebook computer, a digital photo frame, a navigator and so on. The illumination device provided by the embodiment of the disclosure can be used as, for example, the backlight module of a liquid crystal display device, the lamps for decoration or illumination and so on. The display device comprises the light emitting unit as described in embodiment 1.

In the electronic device of the embodiment of the disclosure, using the graphene as the material of the light emitting layer 3 of the light emitting unit, using the first electrode 1 and the second electrode 2 to inject holes and electrons into the light emitting layer 3, upon applying different voltages to the light emitting layer 3, the light emitting layer 3 can emit light at a single wavelength. Compared with the light with wavelengths in a range of value emitted by a light emitting layer 3 made of an organic material, the embodiment of the disclosure enlarges the color gamut of light, makes the colors of the display device more vivid, and improves users' experience. In addition, the graphene can be further used for the hole injection layer 7 and the electron injection layer 6 of the light emitting unit, and the oxidation degrees of the graphene of the hole injection layer 7, the electron injection layer 6 and the light emitting layer 3 are different from each other. The hole injection layer 7 and the electron injection layer 6 made of the graphene can improve the injection rate of holes and electrons into the light emitting layer 3, reduce the energy loss of electrons and holes in the transporting process and improve the luminance of display device.

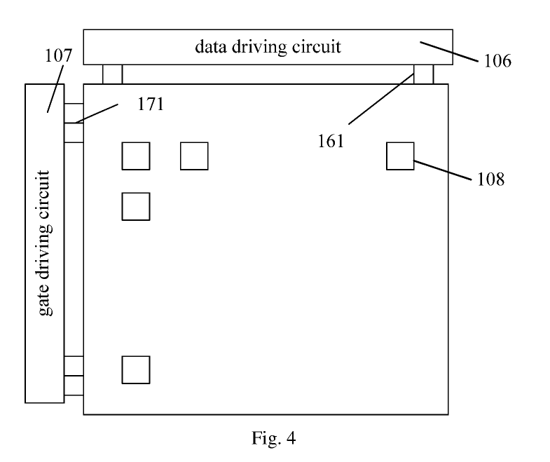

As shown in FIG. 4, the display device can comprise a data driving circuit 106 and a gate driving circuit 107 to provide data signals and gate signals, respectively. The display device comprises a plurality of pixels 108 arranged in an array, the data drive circuit 106 is electrically connected with the pixels 108 through the data lines 161, and the gate drive circuit 107 is electrically connected with the pixels 108 through the gate lines 171. Different pixels 108 can emit light with different colors (such as red light, green light, blue light or white light) when applied with desired voltages where the corresponding gate lines 171 and the data lines 161 are selected. For example, the driving voltage applied to a red pixel is 0˜15V, the driving voltage applied to a green pixel is 15˜30V, and the driving voltage applied to a blue pixel is 35˜50V.

### Embodiment 4

The embodiment of the disclosure provides a method for manufacturing a light emitting unit, and as shown in FIG. 2, an example of the method comprises the following steps:

Step 101: providing a first electrode 1, forming a light emitting layer 3 on the first electrode 1, a material of the light emitting layer 3 comprising graphene.

Step 102: forming a second electrode 2 on the light emitting layer 3.

The light emitting unit of the present embodiment, for example, can be manufactured on a substrate made of glass or plastic. Before manufacturing the light emitting unit, a buffer layer, a circuit layer (comprising circuit structures, such as switching transistors, driving transistors and capacitors, etc.) and so on can have been prepared on the substrate. In the present embodiment of the disclosure, the first electrode 1 can be used as a cathode, the second electrode 2 can be used as an anode, and the first electrode 1 and the second electrode 2 transport electrons and holes into the light emitting layer 3, respectively. Graphene, for example, graphene oxidized to a certain degree, is elected as the material of the light emitting layer 3. For example, by applying different voltages to the graphene oxidized to a certain degree, the graphene can emit red light, green light, or blue light at a single wavelength.

The anode and the cathode can be made of known materials. For example, the anode can comprise materials, such as SnO₂, ITO and so on. The cathode can comprise active metals, such as Li, Mg, Ca and so on and alloys, such as alloys of Ag, Al, In and so on.

In order to apply graphene, a graphene paste can be prepared first with the organic solvent, and then the graphene paste can be coated on the structures that have been prepared on the substrate to form a thin film, or the graphene can also be formed on the substrate by ink-jet printing method.

In the embodiment of the disclosure, a ratio of the number of carbon atoms to the number of oxygen atoms in the graphene of the light emitting layer 3 can be greater than or equal to 0.5 and less than or equal to 0.77.

In the light emitting unit of the embodiment of the disclosure, using the graphene as the material of the light emitting layer 3 of the light emitting unit, using the first electrode 1 and the second electrode 2 to inject holes and electrons into the light emitting layer 3, upon applying different voltages to the light emitting layer 3, the light emitting layer 3 can emit light at a single wavelength. Compared with the light with wavelengths in a range of value emitted by a light emitting layer 3 made of an organic material, the present embodiment of the disclosure enlarges the color gamut of light, makes the colors of display more vivid, and improves the users' experience.

### Embodiment 5

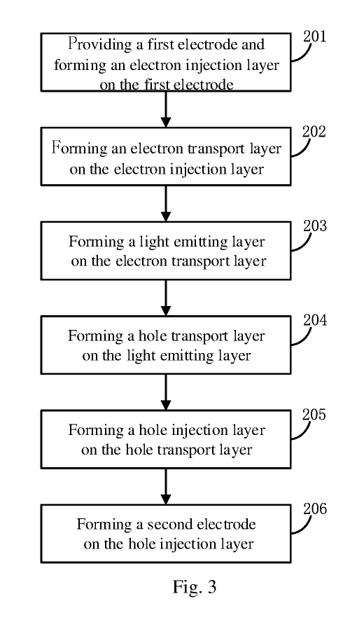

The present embodiment of the disclosure provides a method for manufacturing a light emitting unit, and as shown in FIG. 3, an example of the method comprises the following steps:

Step 201: providing a first electrode 1, forming an electron injection layer 6 on the first electrode 1, wherein a material of the electron injection layer 6 comprises graphene.

In the embodiment of the disclosure, the first electrode 1 can be a cathode, and the cathode transport electrons to the electron injection layer 6. Graphene, for example, graphene oxidized to a certain degree is elected as the material of the light emitting layer 3.

In the embodiment of the disclosure, a ratio of the number of carbon atoms to the number of oxygen atoms in the graphene of the electron injection layer 6 can be greater than or equal to 0.57 and less than or equal to 1.

In the embodiment of the disclosure, in the case where the light emitting unit is used for an AMOLED display device, as shown in FIG. 1, a first electrode 1 of a light emitting unit can be formed on an array substrate 8, and the first electrode 1 can be electrically connected to an electrode (e.g., the drain electrode) of a transistor on the array substrate through a via hole.

Step 202: forming an electron transport layer 4 on the electron injection layer 6.

In the embodiment of the disclosure, the electron injection layer 6 is used for injecting electrons to the electron transport layer 4.

Step 203: forming a light emitting layer 3 on the electron transport layer 4 wherein the material of the light emitting layer 3 comprises graphene.

In the embodiment of the disclosure, the electron transport layer 4 is used for transporting electrons to the light emitting layer 3.

In the embodiment of the disclosure, graphene oxidized to a certain degree can be used as the material of the light emitting layer 3, and upon applying different voltages to the graphene, the graphene can emit red light, green light, or blue light at a single wavelength.

In the embodiment of the disclosure, a ratio of the number of carbon atoms to the number of oxygen atoms in the graphene oxidized to a certain degree can be greater than or equal to 0.5 and less than or equal to 0.77.

Step 204: forming a hole transport layer 5 on the light emitting layer 3.

The hole transport layer 5 is used for transporting holes to the light emitting layer 3.

Step 205: forming a hole injection layer 7 on the hole transport layer 5, wherein the material of the hole injection layer 7 comprises graphene.

In the embodiment of the disclosure, a ratio of the number of carbon atoms to the number of oxygen atoms in the graphene of hole injection layer 7 can be greater than or equal to 0 and less than or equal to 0.48.

In the embodiment of the disclosure, the hole injection layer 7 is used for injecting holes to the hole transport layer 5.

Step 206: forming a second electrode 2 on the hole injection layer 7.

In the embodiment of the disclosure, the second electrode 2 can be an anode, and the anode is used for transporting holes to the hole injection layer 7.

In the light emitting unit of the embodiment of the disclosure, using the graphene as the material of the light emitting layer 3 of the light emitting unit, using the first electrode 1 and the second electrode 2 to inject holes and electrons into the light emitting layer 3, upon applying different voltages to the light emitting layer 3, the light emitting layer 3 can emit light at a single wavelength. Compared with the light with wavelengths in a range of value emitted by a light emitting layer 3 made of an organic material, the embodiment of the disclosure enlarges the color gamut of light, makes the colors of display more vivid, and improves the users' experience. In addition, the graphene can be further used for the hole injection layer 7 and the electron injection layer 6 of the light emitting unit, and the oxidation degrees of the graphene of the hole injection layer 7, the electron injection layer 6 and the light emitting layer 3 are different from each other. The hole injection layer 7 and the electron injection layer 6 made of the graphene can improve the injection rate of holes and electrons into the light emitting layer 3, reduce the energy loss of electrons and holes in the transporting process and improve the luminance of display device.

What are described above is related to the illustrative embodiments of the disclosure only and not limitative to the scope of the disclosure. Any modification, equivalent replacement, improvement and combination of the embodiment within the spirit and principles of the present disclosure should be included in the scope of the disclosure.

The application claims priority of Chinese Patent Application No. 201610371608.4 filed on May 30, 2016, the disclosure of which is incorporated herein by reference in its entirety as part of the present application.

1. A light emitting unit, comprising: a first electrode, a second electrode and a light emitting layer between the first electrode and the second electrode;
wherein a material of the light emitting layer comprises graphene.

2. The light emitting unit according to claim 1, wherein the graphene is graphene oxide.

3. The light emitting unit according to claim 1, further comprising an electron transport layer and a hole transport layer;
wherein the electron transport layer is arranged between the light emitting layer and the first electrode and the hole transport layer is arranged between the light emitting layer and the second electrode.

4. The light emitting unit according to claim 1, further comprising an electron injection layer and a hole injection layer;
wherein the electron injection layer is arranged between the electron transport layer and the first electrode,
the hole injection layer is arranged between the hole transport layer and the second electrode, and
a material of the electron injection layer and a material of the hole injection layer comprise graphene.

5. The light emitting unit according to claim 4, wherein oxidation degrees of the graphene of the electron injection layer, the graphene of the hole injection layer and the graphene of the light emitting layer are different from each other.

6. The light emitting unit according to claim 5, wherein a ratio of a number of oxygen atoms to a number of carbon atoms in the graphene of the hole injection layer is greater than or equal to 0 and less than or equal to 0.48, and
a ratio of a number of oxygen atoms to a number of carbon atoms in the graphene of the electrons injected layer is greater than or equal to 0.57 and less than or equal to 1.

7. The light emitting unit according to claim 2, wherein a ratio of a number of oxygen atoms to a number of carbon atoms in the graphene of the light emitting layer is greater than or equal to 0.5 and less than or equal to 0.77.

8. The light emitting unit according to claim 1, wherein
where a voltage applied across the first electrode and the second electrode is 0˜15V, the light emitting layer emits red light at a single wavelength;
where a voltage applied across the first electrode and the second electrode is 15˜30V, the light emitting layer emits green light at a single wavelength; and
where a voltage applied across the first electrode and the second electrode is 35˜50V, the light emitting layer emits blue light at a single wavelength.

9. An electronic panel, comprising the light emitting unit according to claim 1.

10. A display device, comprising the light emitting unit according to claim 1.

11. A method for manufacturing a light emitting unit, comprising:
providing a first electrode and a second electrode;
forming a light emitting layer between the first electrode and the second electrode, wherein a material of the light emitting layer comprises graphene.

12. The light emitting unit according to claim 2, further comprising an electron transport layer and a hole transport layer;
wherein the electron transport layer is arranged between the light emitting layer and the first electrode and the hole transport layer is arranged between the light emitting layer and the second electrode.

13. The light emitting unit according to claim 2, further comprising an electron injection layer and a hole injection layer;
wherein the electron injection layer is arranged between the electron transport layer and the first electrode,
the hole injection layer is arranged between the hole transport layer and the second electrode, and
a material of the electron injection layer and a material of the hole injection layer comprise graphene.

14. The light emitting unit according to claim 13, wherein oxidation degrees of the graphene of the electron injection layer, the graphene of the hole injection layer and the graphene of the light emitting layer are different from each other.

15. The light emitting unit according to claim 14, wherein a ratio of a number of oxygen atoms to a number of carbon atoms in the graphene of the hole injection layer is greater than or equal to 0 and less than or equal to 0.48, and
a ratio of a number of oxygen atoms to a number of carbon atoms in the graphene of the electrons injected layer is greater than or equal to 0.57 and less than or equal to 1.

16. The light emitting unit according to claim 2, wherein
where a voltage applied across the first electrode and the second electrode is 0˜15V, the light emitting layer emits red light at a single wavelength;
where a voltage applied across the first electrode and the second electrode is 15˜30V, the light emitting layer emits green light at a single wavelength; and
where a voltage applied across the first electrode and the second electrode is 35˜50V, the light emitting layer emits blue light at a single wavelength.

17. The light emitting unit according to claim 3, further comprising an electron injection layer and a hole injection layer;
wherein the electron injection layer is arranged between the electron transport layer and the first electrode,
the hole injection layer is arranged between the hole transport layer and the second electrode, and
a material of the electron injection layer and a material of the hole injection layer comprise graphene.

18. The light emitting unit according to claim 17, wherein oxidation degrees of the graphene of the electron injection layer, the graphene of the hole injection layer and the graphene of the light emitting layer are different from each other.

19. The light emitting unit according to claim 18, wherein a ratio of a number of oxygen atoms to a number of carbon atoms in the graphene of the hole injection layer is greater than or equal to 0 and less than or equal to 0.48, and
a ratio of a number of oxygen atoms to a number of carbon atoms in the graphene of the electrons injected layer is greater than or equal to 0.57 and less than or equal to 1.
